(19) United States
(12) Patent Application Publication
(10) Pub. No.: US 2010/0270527 A1
(43) Pub. Date: Oct. 28, 2010

(54) PHASE-CHANGE MEMORY DEVICE AND METHOD OF MANUFACTURING THE PHASE-CHANGE MEMORY DEVICE

(75) Inventor: Kenji Sawamura, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/558,753

(22) Filed: Sep. 14, 2009

(30) Foreign Application Priority Data
Apr. 27, 2009 (JP) 2009-107334

(51) Int. Cl. H01L 47/00; H01L 21/06

(52) U.S. Cl. 257/2; 438/102; 257/E21.068; 257/E47.001

(57) ABSTRACT

A phase-change memory device has a plurality of first wiring lines; a plurality of memory cells that are provided on the plurality of first wiring lines; a plurality of second wiring lines that are provided on the plurality of memory cells, respectively; and an interlayer insulating film that is formed between the plurality of first wiring lines and the plurality of second wiring lines and insulates the plurality of first wiring lines from the plurality of second wiring lines; wherein each of the memory cells includes a heat source element that is supplied with a current and generates heat and a phase-change element that is changed to an amorphous state or a crystalline state according to a cooling speed after being heated by the heat source element, a resistance value of the phase-change element varying with the change in the state, and wherein a void is formed between the two adjacent memory cells in the interlayer insulating film.

### CROSS-REFERENCE TO RELATED APPLICATION

This application is based upon and claims the benefit of priority from the prior Japanese Patent Application No. 2009-107334, filed on Apr. 27, 2009, the entire contents of which are incorporated herein by reference.

### BACKGROUND OF THE INVENTION

1. Field of the Invention

The present invention relates to a phase-change memory device including phase-change elements whose resistance value is changed when its state is changed to an amorphous state or a crystalline state.

2. Background Art

In the conventional art, each of the memory cells of a phase-change memory device, which is a switching structure, includes a heat source element and a phase-change element provided on the heat source element.

The heat source element is supplied with a current and generates heat, and the crystalline state of the phase-change element provided on the heat source element is changed. Specifically, the phase-change element is changed between two states, such as an amorphous state and a crystalline state.

For example, when the phase-change element is heated and cooled down, the phase-change element is changed from the amorphous state to the crystalline state. When the phase-change element is heated again and cooled down rapidly, the phase-change element returns from the crystalline state to the amorphous state. The change in state causes the resistance value of the phase-change element to vary. The phase-change element has a large resistance value in the amorphous state and has a low resistance value in the crystalline state.

The resistance value of the phase-change element defines two memory states allocated with, for example, bit values ‘0 ’ and ‘1 ’. That is, the memory cell is a nonvolatile memory that holds data even when power is turned on or off.

However, when the degree of integration of the memory cells in the same plane is increased, the memory states of each memory cells are affected by heat generated by the heat source elements of adjacent memory cells.

The crystalline states of phase-change elements other than a phase-change element, which is a data write target, are changed by the heat, which causes data stored in the memory cell, which is not a data write target, to be damaged.

In order to solve the above-mentioned problem, a phase-change memory device has been proposed in which a porous oxide film having low heat conductivity is provided at both sides of a heater which heats a phase-change material forming the memory cell, thereby reducing heat dissipation from the end of the phase-change material in the vicinity of the heater (for example, see Japanese Patent Laid-Open No. 2008-530790).

However, in the conventional phase-change memory device, the examination has been conducted on only one memory cell region. That is, JP-A 2008-530790 (KOKAI) does not disclose the influence of heat generated by the heater of the memory cell on the phase-change material of adjacent memory cells.

### SUMMARY OF THE INVENTION

According to one aspect of the present invention, there is provided: a phase-change memory device comprising:

a plurality of first wiring lines;

a plurality of memory cells that are provided on the plurality of first wiring lines;

a plurality of second wiring lines that are provided on the plurality of memory cells, respectively; and

an interlayer insulating film that is formed between the plurality of first wiring lines and the plurality of second wiring lines and insulates the plurality of first wiring lines from the plurality of second wiring lines;

wherein each of the memory cells includes a heat source element that is supplied with a current and generates heat and a phase-change element that is changed to an amorphous state or a crystalline state according to a cooling speed after being heated by the heat source element, a resistance value of the phase-change element varying with the change in the state, and

wherein a void is formed between the two adjacent memory cells in the interlayer insulating film.

According to another aspect of the present invention, there is provided: a method of manufacturing a phase-change memory device, the method comprising:

forming a first interlayer insulating film on a region including first wiring lines;

selectively etching the first interlayer insulating film to form a plurality of contact holes that pass through the first interlayer insulating film and reach the first wiring lines;

depositing a heat source material at least in the plurality of contact holes;

etching the heat source material deposited in each of the contact holes to a predetermined height of the contact hole to form a plurality of heat source elements;

forming a phase-change material on the heat source elements in the contact holes to form a plurality of phase-change elements;

selectively etching an upper surface of the first interlayer insulating film until an entire side surface of each of the phase-change elements is exposed and a portion of a side surface of each of the heat source elements is exposed;

forming a second interlayer insulating film on the first interlayer insulating film and the phase-change elements such that a void is formed between the two adjacent phase-change elements;

planarizing an upper surface of the second interlayer insulating film such that the upper surfaces of the phase-change elements are exposed; and

forming second wiring lines on the phase-change elements.

According to still another aspect of the present invention, there is provided: a method of manufacturing a phase-change memory device, the method comprising:

forming a heat source material layer on a region including a plurality of first wiring lines;

forming a phase-change material layer on the heat source material layer;

selectively etching the phase-change material layer and the heat source material layer to form heat source elements and phase-change elements;

forming an interlayer insulating film on the region including the plurality of first wiring lines such that a void is formed between the two adjacent phase-change elements;

planarizing an upper part of the interlayer insulating film such that the upper surfaces of the phase-change elements are exposed; and

forming second wiring lines on the phase-change elements.

### BRIEF DESCRIPTION OF THE DRAWINGS

FIG. 1 is a diagram illustrating a structure in the vicinity of a memory cell region in which a plurality of memory cells M are arranged in a phase-change memory device 100 according to a first embodiment;

FIG. 2 is a longitudinal cross-sectional view illustrating a region including the memory cells M arranged along the bit line BL shown in FIG. 1;

FIG. 3A is a cross-sectional view illustrating a process of a method of manufacturing a vicinity of a memory cell region of the phase-change memory device 100 shown in FIG. 1;

FIG. 3B is a cross-sectional view illustrating a process of the method of manufacturing the vicinity of the memory cell region of the phase-change memory device 100 shown in FIG. 1, and is continuous from FIG. 3A;

FIG. 3C is a cross-sectional view illustrating a process of the method of manufacturing the vicinity of the memory cell region of the phase-change memory device 100 shown in FIG. 1, and is continuous from FIG. 3B;

FIG. 4A is a cross-sectional view illustrating a process of the method of manufacturing the vicinity of the memory cell region of the phase-change memory device 100 shown in FIG. 1, and is continuous from FIG. 3C;

FIG. 4B is a cross-sectional view illustrating a process of the method of manufacturing the vicinity of the memory cell region of the phase-change memory device 100 shown in FIG. 1, and is continuous from FIG. 4A;

FIG. 4C is a cross-sectional view illustrating a process of the method of manufacturing the vicinity of the memory cell region of the phase-change memory device 100 shown in FIG. 1, and is continuous from FIG. 4B;

FIG. 5A is a cross-sectional view illustrating a process of the method of manufacturing the vicinity of the memory cell region of the phase-change memory device 100 shown in FIG. 1, and is continuous from FIG. 4C;

FIG. 5B is a cross-sectional view illustrating a process of the method of manufacturing the vicinity of the memory cell region of the phase-change memory device 100 shown in FIG. 1, and is continuous from FIG. 5A;

FIG. 6 is a diagram illustrating a structure in the vicinity of a memory cell region in which a plurality of memory cells M are arranged in a phase-change memory device 200 according to the second embodiment;

FIG. 7 is a longitudinal cross-sectional view illustrating a region including the memory cells M arranged along the bit lines BL shown in FIG. 6;

FIG. 8A is a cross-sectional view illustrating a process of a method of manufacturing a vicinity of a memory cell region of the phase-change memory device 200 shown in FIG. 6;

FIG. 8B is a cross-sectional view illustrating a process of the method of manufacturing the vicinity of the memory cell region of the phase-change memory device 200 shown in FIG. 6, and is continuous from FIG. 8A;

FIG. 8C is a cross-sectional view illustrating a process of the method of manufacturing the vicinity of the memory cell region of the phase-change memory device 200 shown in FIG. 6, and is continuous from FIG. 8B;

FIG. 9A is a cross-sectional view illustrating a process of the method of manufacturing the vicinity of the memory cell region of the phase-change memory device 200 shown in FIG. 6, and is continuous from FIG. 8C;

FIG. 9B is a cross-sectional view illustrating a process of the method of manufacturing the vicinity of the memory cell region of the phase-change memory device 200 shown in FIG. 6, and is continuous from FIG. 9A;

FIG. 9C is a cross-sectional view illustrating a process of the method of manufacturing the vicinity of the memory cell region of the phase-change memory device 200 shown in FIG. 6, and is continuous from FIG. 9B;

FIG. 10A is a cross-sectional view illustrating a process of the method of manufacturing the vicinity of the memory cell region of the phase-change memory device 200 shown in FIG. 6, and is continuous from FIG. 9C;

FIG. 10B is a cross-sectional view illustrating a process of the method of manufacturing the vicinity of the memory cell region of the phase-change memory device 200 shown in FIG. 6, and is continuous from FIG. 10A;

FIG. 10C is a cross-sectional view illustrating a process of the method of manufacturing the vicinity of the memory cell region of the phase-change memory device 200 shown in FIG. 6, and is continuous from FIG. 10B;

FIG. 11 is a cross-sectional view illustrating a process of the method of manufacturing the vicinity of the memory cell region of the phase-change memory device 200 shown in FIG. 6, and is continuous from FIG. 10C;

FIG. 12 is a diagram illustrating a structure in the vicinity of a memory cell region in which a plurality of memory cells M are arranged in a phase-change memory device 300 according to the third embodiment;

FIG. 13 is a longitudinal cross-sectional view illustrating a region including the memory cells M arranged along the bit lines BL shown in FIG. 12;

FIG. 14A is a cross-sectional view illustrating a process of a method of manufacturing a vicinity of a memory cell region of the phase-change memory device 300 shown in FIG. 12;

FIG. 14B is a cross-sectional view illustrating a process of the method of manufacturing the vicinity of the memory cell region of the phase-change memory device 300 shown in FIG. 12, and is continuous from FIG. 14A;

FIG. 14C is a cross-sectional view illustrating a process of the method of manufacturing the vicinity of the memory cell region of the phase-change memory device 300 shown in FIG. 12, and is continuous from FIG. 14B;

FIG. 15A is a cross-sectional view illustrating a process of the method of manufacturing the vicinity of the memory cell region of the phase-change memory device 300 shown in FIG. 12, and is continuous from FIG. 14C; and

FIG. 15B is a cross-sectional view illustrating a process of the method of manufacturing the vicinity of the memory cell region of the phase-change memory device 300 shown in FIG. 12, and is continuous from FIG. 15A.

### DETAILED DESCRIPTION

Hereinafter, exemplary embodiments of the invention will be described with reference to the accompanying drawings. In the following embodiments, for example, a structure in which word lines (wring lines) WL are provided above bit lines (wiring lines) BL will be described. However, the invention may be applied to a structure in which the bit lines (wiring lines) BL are provided above the word lines (wiring lines) WL.

### First Embodiment

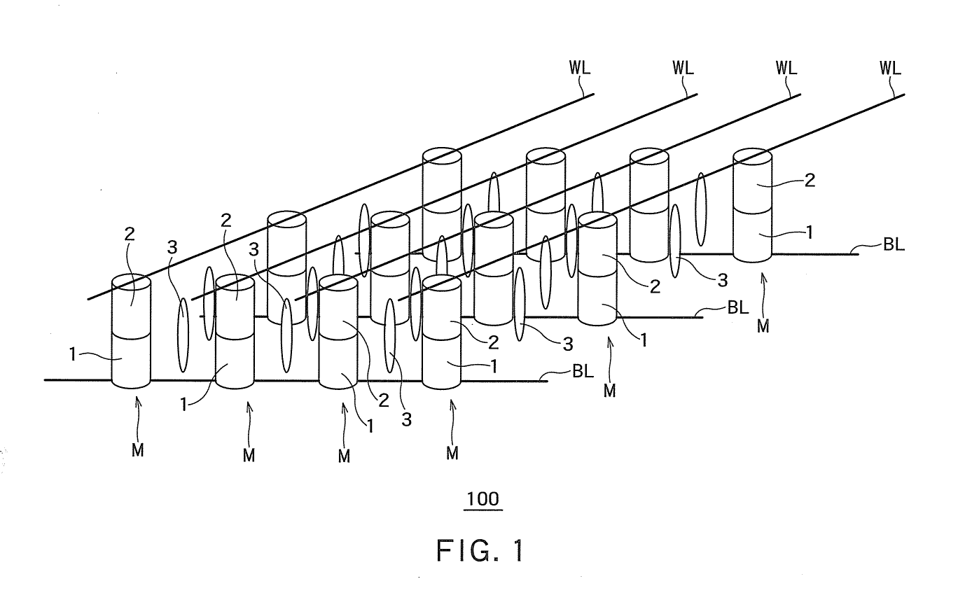

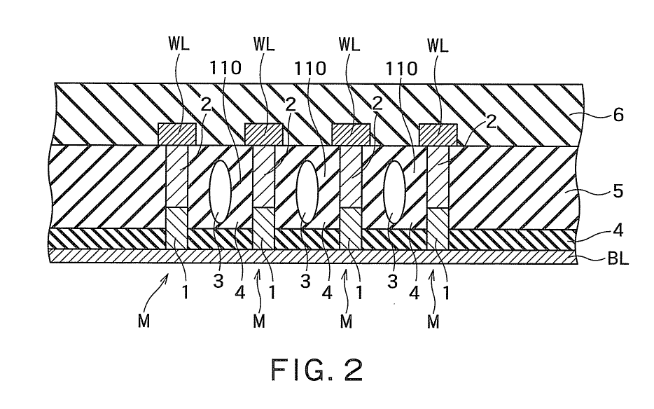

FIG. 1 is a diagram illustrating a structure in the vicinity of a memory cell region in which a plurality of memory cells M are arranged in a phase-change memory device 100 according to a first embodiment. FIG. 2 is a longitudinal cross-sectional view illustrating a region including the memory cells M arranged along the bit line BL shown in FIG. 1. For convenience, in FIG. 1, the interlayer insulating films shown in FIG. 2 are omitted. In addition, in FIG. 1, the bit lines BL and the word lines WL are briefly shown.

As shown in FIGS. 1 and 2, the phase-change memory device 100 includes a plurality of bit lines (wiring lines) BL, a plurality of memory cells M, a plurality of word lines (wiring lines) WL, and interlayer insulating films 4, 5, and 6.

For example, the plurality of bit lines (wiring lines) BL are arranged in parallel to each other on an insulating film (not shown) formed on a semiconductor substrate (not shown).

The plurality of memory cells M are provided on the plurality of bit lines BL so as to be electrically connected to the bit lines BL. Each of the memory cells M includes a heat source element 1 and a phase-change element 2. The memory cells M have a cylindrical shape since it is formed in a contact hole.

The heat source element 1 is arranged on the bit line BL so as to be electrically connected to the bit line BL. A current corresponding to a potential difference between the bit line BL and the word line WL flows through the heat source element 1 such that the heat source element 1 generates heat. The phase-change element 2 is heated by the heat generated by the heat source element 1.

The phase-change element 2 is provided on the heat source element 1, and is changed to an amorphous state or a crystalline state according to a cooling rate after being heated by the heat source element 1. The resistance value of the phase-change element 2 is changed with the variation in the state. That is, for example, when the phase-change element 2 is heated and cooled down slowly, the state of the phase-change element 2 is changed from the amorphous state to the crystalline state. When the phase-change element 2 is heated again and supercooled, the state of the phase-change element 2 returns from the crystalline state to the amorphous state. This change in state causes the resistance value of the phase-change element 2 to vary. The phase-change element has a large resistance value in the amorphous state and has a low resistance value in the crystalline state. The phase-change element 2 includes a phase-change material, such as chalcogenide or a material that does not include chalcogen. The chalcogenide is selected from, for example, GeSbTe and AgInSbTe. The material that does not include chalcogen is selected from, for example, GeSb, GaSb, and GeGaSb.

The resistance value of the phase-change element 2 defines two memory states allocated with, for example, bit values ‘0 ’ and ‘1 ’. That is, the memory cell is a nonvolatile memory that holds data even when power is turned off.

The plurality of word lines (wiring lines) WL are arranged on the plurality of memory cells M so as to be parallel thereto. The word line WL is electrically connected to the phase-change element 2 of the memory cell M. As described above, current flows to the heat source element 1 and the phase-change element 2 by the potential difference between the word line WL and the bit line BL.

The interlayer insulating films 4 and 5 are formed between the plurality of bit lines BL and the plurality of word lines WL and insulate the plurality of bit lines BL from the plurality of word lines WL. The interlayer insulating film 6 is formed on the interlayer insulating film 5 and the word lines WL. The interlayer insulating films 4, 5, and 6 are, for example, silicon oxide films.

Voids 3 are formed in each space 110 between each pair of two adjacent memory cells in the interlayer insulating film 4. In particular, in the first embodiment, the voids 3 are formed between the phase-change elements 2 and between the upper parts of the heat source elements 1 of two adjacent memory cells M in the interlayer insulating film 4. The voids 3 are formed so as to extend from a space between two adjacent phase-change elements 2 to a space between the upper parts of adjacent heat source elements 1. In general, since the interlayer insulating film is uniformly formed in a wafer, the voids 3 are formed so as to have a segment that divides the shortest distance between two adjacent memory cells (two adjacent heat source elements and two adjacent phase-change elements) into two equal parts and are vertical to the surface of the wafer (the segment is parallel to the direction in which the memory cells extend).

The voids 3 prevent heat generated by the heat source element 1 of a certain memory cell M from being transmitted to the phase-change elements 2 of two adjacent memory cells M. In this way, it is possible to reduce the influence of the heat generated by the heat source element 1 of a certain memory cell M on the phase-change elements 2 of adjacent memory cells M (variation in the resistance values of the phase-change elements 2). Therefore, for example, it is possible to prevent data from being erroneously written to the memory cell M, which is not a data write target, or data from being erroneously erased from the memory cell M, which is not a data erase target.

That is, according to the phase-change memory device 100, it is possible to improve the degree of integration and reduce the influence of heat generated by the heat source element of a certain memory cell on the phase-change elements of adjacent memory cells.

In FIG. 1, the voids 3 are provided only between the memory cells that are most closely adjacent to each other (adjacent memory cells connected to the same bit line or the same word line). However, the voids 3 may be provided between two adjacent memory cells on a diagonal line according to the relationship between the gap between the memory cells and the coverage of the interlayer insulating film. The above-mentioned structure may be used in order to reduce the influence of the memory cells adjacent to each other on the diagonal line.

Next, an example of a method of manufacturing the phase-change memory device 100 having the above-mentioned structure will be described.

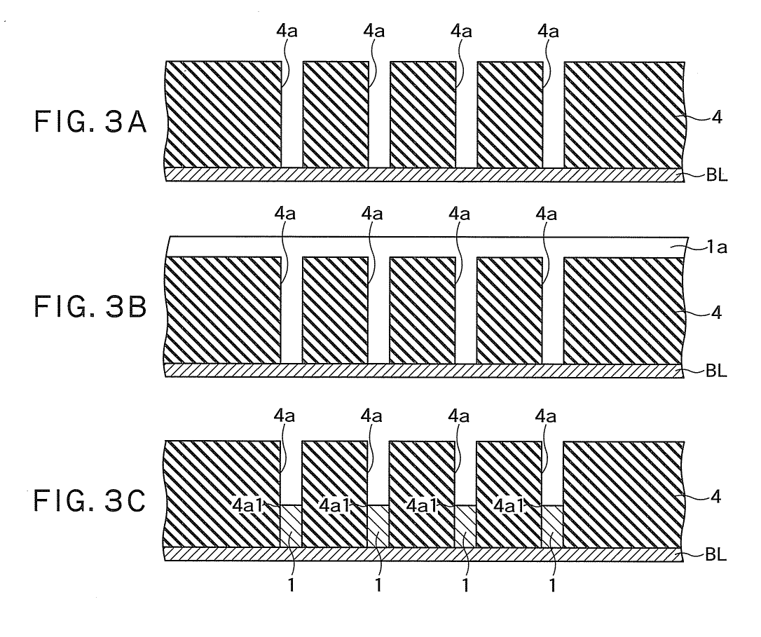

FIGS. 3 to 5 are cross-sectional views illustrating processes of a method of manufacturing a vicinity of a memory cell region of the phase-change memory device 100 shown in FIG. 1. In addition, FIGS. 3 to 5 are longitudinal cross-sectional views illustrating a region including the memory cells M arranged along the bit lines BL shown in FIG. 1, similar to FIG. 2.

First, for example, a chemical vapor deposition (CVD) method or a physical vapor deposition (PVD) method is used to form the interlayer insulating film 4, which includes, for example, a silicon oxide film, on a region including a plurality of bit lines BL parallel to each other. Then, the interlayer insulating film 4 is selectively etched using, for example, a photoresist (not shown) as a mask. In this way, a plurality of contact holes 4a that pass through the interlayer insulating film 4 and reach the bit lines BL are formed (FIG. 3 A).

Then, as shown in FIG. 3 B, a heat source material 1a that is supplied with a current and generates heat is deposited in the contact holes 4a and on the interlayer insulating film 4 by, for example, the CVD method or the PVD method.

Then, as shown in FIG. 3 C, the heat source material 1a deposited in the contact holes 4a is etched to a predetermined height 4a1 of the contact hole 4a by, for example, a dry etching method. In this way, the heat source elements 1 are formed.

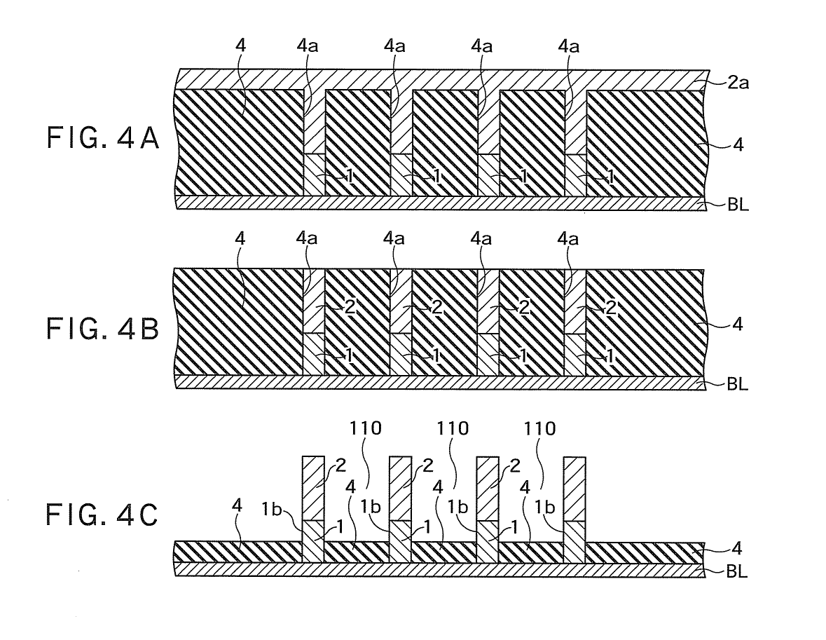

Then, as shown in FIG. 4 A, a phase-change material 2a, such as GeSbTe or AgInSbTe, is deposited on the interlayer insulating film 4 and the heat source elements 1 in the contact holes 4a by, for example, the CVD method or the PVD method. In addition, the phase-change material 2a on the interlayer insulating film 4 is removed by, for example, the dry etching method. In this way, the phase-change elements 2 are formed on the heat source elements 1 in the contact holes 4a (FIG. 4 B).

Then, as shown in FIG. 4 C, an upper part of the interlayer insulating film 4 is selectively etched until the entire side surface of the phase-change element 2 is exposed and a portion of a side surface 1b of the heat source element 1 is exposed.

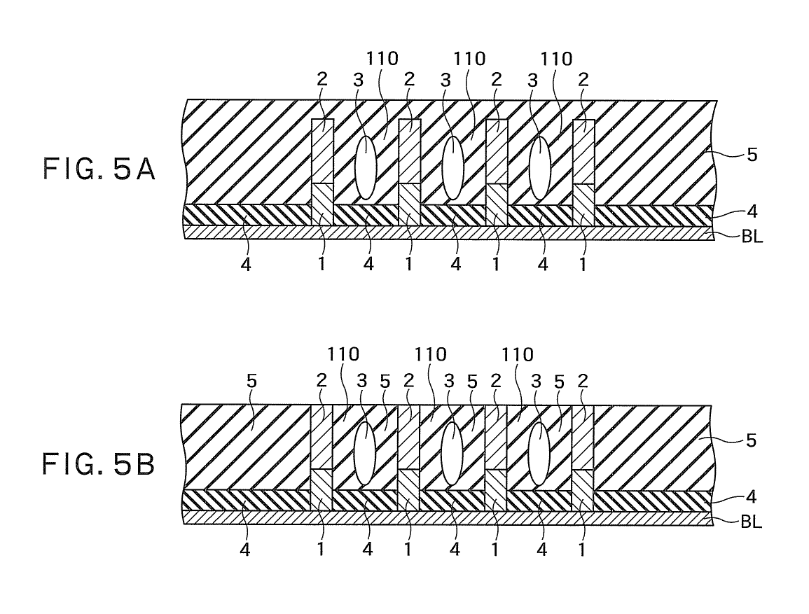

Then, as shown in FIG. 5 A, an insulating material, such as a silicon oxide film, is deposited on the interlayer insulating film 4 and the phase-change elements 2 by, for example, the CVD method or the PVD method such that the voids 3 are formed in the spaces 110 between two adjacent phase-change elements and between the upper parts of adjacent heat source elements 1. In this way, the interlayer insulating film 5 including the voids 3 is formed. As described above, the voids 3 prevent heat generated by the heat source element 1 of a certain memory cell M from being transmitted to the phase-change elements 2 of adjacent memory cells M.

Then, as shown in FIG. 5 B, for example, the upper surface of the interlayer insulating film 5 is planarized by, for example, a chemical mechanical polishing (CMP) method such that the upper surface of the phase-change element 2 is exposed.

Then, a plurality of word lines WL that are parallel to each other are formed on the phase-change elements 2 by, for example, a photolithography technique. In addition, for example, the interlayer insulating film 6 is formed on the interlayer insulating film 5 and the word lines WL by, for example, the CVD method or the PVD method. In this way, a structure in the vicinity of the memory cell region of the phase-change memory device 100 shown in FIGS. 1 and 2 is completely formed.

As described above, according to the phase-change memory device of the present embodiment, it is possible to improve the degree of integration and reduce the influence of heat generated by the heat source element of a certain memory cell on the phase-change elements of adjacent other memory cells.

In addition, when the voids are formed in the interlayer insulating film, heat conductivity is lowered, the occurrence of defects in a wet process is reduced, and voltage resistance between the memory cells is increased, as compared to a porous oxide film.

### Second Embodiment

In the first embodiment, an example of the structure for preventing heat generated by the heat source element of a certain memory cell from being transmitted to the phase-change elements of adjacent memory cells has been described.

In a second embodiment, another example of the structure for preventing heat generated by the heat source element of a certain memory cell being transmitted to the phase-change elements of adjacent memory cells will be described.

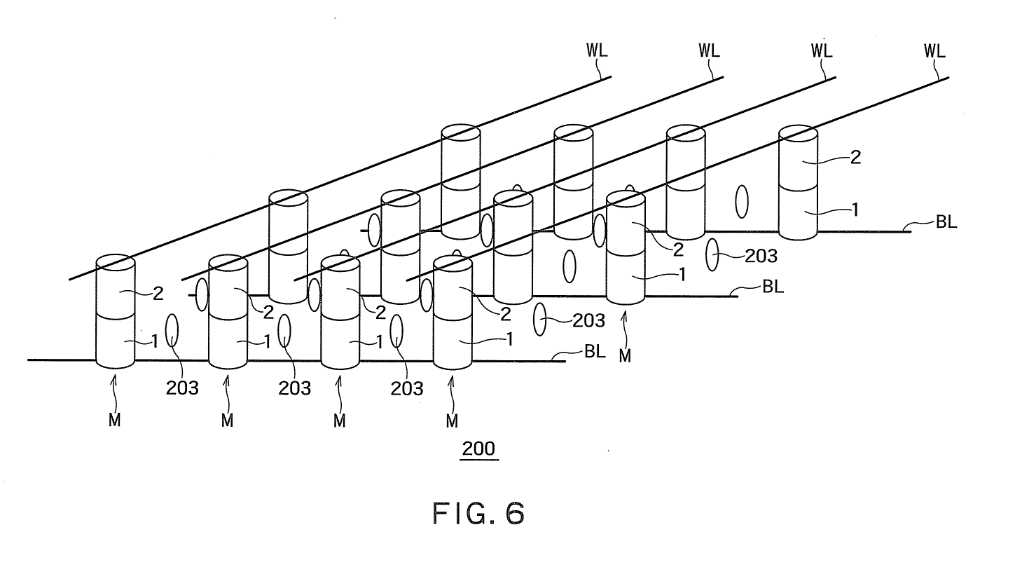

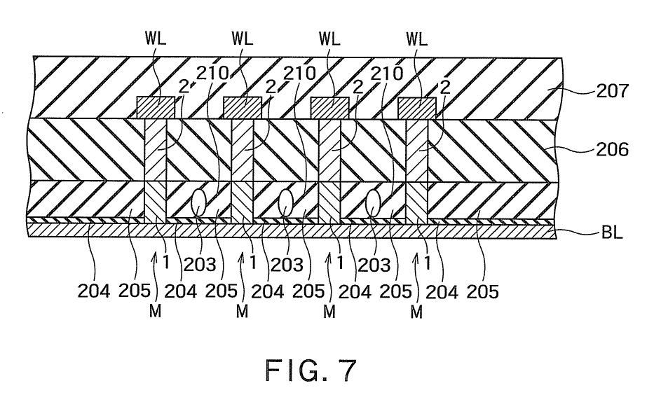

FIG. 6 is a diagram illustrating a structure in the vicinity of a memory cell region in which a plurality of memory cells M are arranged in a phase-change memory device 200 according to the second embodiment. FIG. 7 is a longitudinal cross-sectional view illustrating a region including the memory cells M arranged along the bit lines BL shown in FIG. 6. For convenience, in FIG. 6, the interlayer insulating films shown in FIG. 2 are omitted. In addition, in FIG. 6, bit lines BL and word lines WL are simply presented. In addition, in FIGS. 6 and 7, components denoted by the same reference numerals as those shown in FIGS. 1 and 2 have the similar structure as those according the first embodiment.

As shown in FIGS. 6 and 7, the phase-change memory device 200 includes a plurality of bit lines (wiring lines) BL, a plurality of memory cells M, a plurality of word lines (wiring lines) WL, and interlayer insulating films 204 to 207.

The structure of the phase-change memory device 200 is similar to that of the phase-change memory device 100 according to the first embodiment except for the positions of voids 203. The interlayer insulating films 204, 205, and 206 of the phase-change memory device 200 correspond to the interlayer insulating films 4 and 5 of the phase-change memory device 100 according to the first embodiment In addition, the interlayer insulating film 207 of the phase-change memory device 200 corresponds to the interlayer insulating film 6 of the phase-change memory device 100 according to the first embodiment.

The voids 203 are formed in a space 210 between the upper parts of the heat source elements 1 of adjacent memory cells M in the interlayer insulating film 205. That is, the void 203 is formed in the range from the height of upper surface of the heat source element 1 to the height of the upper surface of the phase-change element.

The voids 203 prevent heat generated by the heat source element 1 of a certain memory cell M from being transmitted to the phase-change elements 2 of adjacent other memory cells M. In this way, it is possible to reduce the influence of the heat generated by the heat source element 1 of a certain memory cell M on the phase-change elements 2 of adjacent other memory cells M (variation in the resistance values of the phase-change elements 2). Therefore, for example, it is possible to prevent data from being erroneously written to the memory cell M, which is not a data write target, or data from being erroneously erased from the memory cell M, which is not a data erase target.

That is, according to the phase-change memory device 200, it is possible to improve the degree of integration and reduce the influence of heat generated by the heat source element of a certain memory cell on the phase-change elements of adjacent other memory cells.

In FIG. 6, the voids 203 are provided only between the memory cells that are most closely adjacent to each other (adjacent memory cells connected to the same bit line or the same word line). However, the voids 203 may be provided between adjacent memory cells on a diagonal line according to the relationship between the gap between the memory cells and the coverage of the interlayer insulating film. The above-mentioned structure may be used in order to reduce the influence of the memory cells adjacent to each other on the diagonal line.

Next, an example of a method of manufacturing the phase-change memory device 200 having the above-mentioned structure will be described.

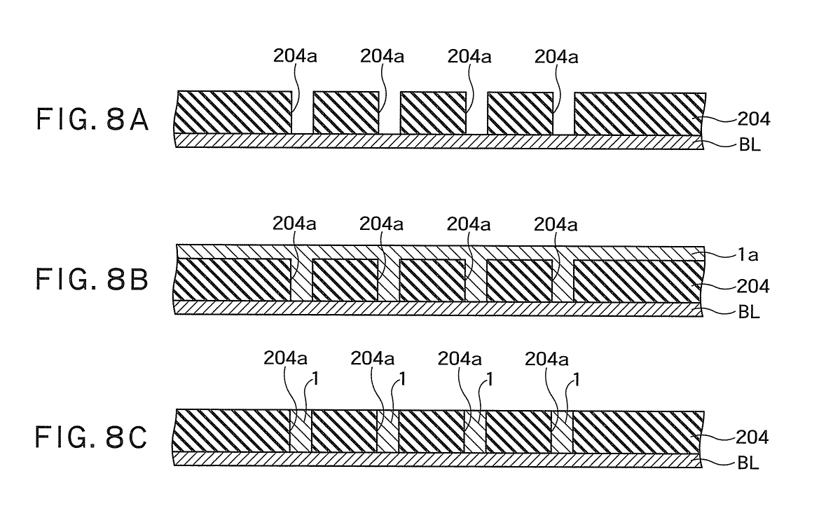

FIGS. 8 to 11 are cross-sectional views illustrating processes of a method of manufacturing a vicinity of a memory cell region of the phase-change memory device 200 shown in FIG. 6. In addition, FIGS. 8 to 11 are longitudinal cross-sectional views illustrating a region including the memory cells M arranged along the bit lines BL shown in FIG. 6, similar to FIG. 7.

First, for example, the CVD method or the PVD method is used to form the interlayer insulating film 204, which is, for example, a silicon oxide film, on a region including a plurality of bit lines BL parallel to each other. Then, the interlayer insulating film 204 is selectively etched using, for example, a photoresist (not shown) as a mask. In this way, a plurality of contact holes 204a that pass through the interlayer insulating film 204 and reach the bit lines BL are formed (FIG. 8 A).

Then, as shown in FIG. 8 B, a heat source material 1a that is supplied with a current and generates heat is deposited in the plurality of contact holes 204a and on the interlayer insulating film 204 by, for example, the CVD method or the PVD method.

Then, as shown in FIG. 8 C, the heat source material is deposited on the interlayer insulating film 204 is etched by, for example, a dry etching method until the upper surface of the interlayer insulating film 204 is exposed. In this way, the plurality of heat source elements 1 is formed in the plurality of contact holes 204a.

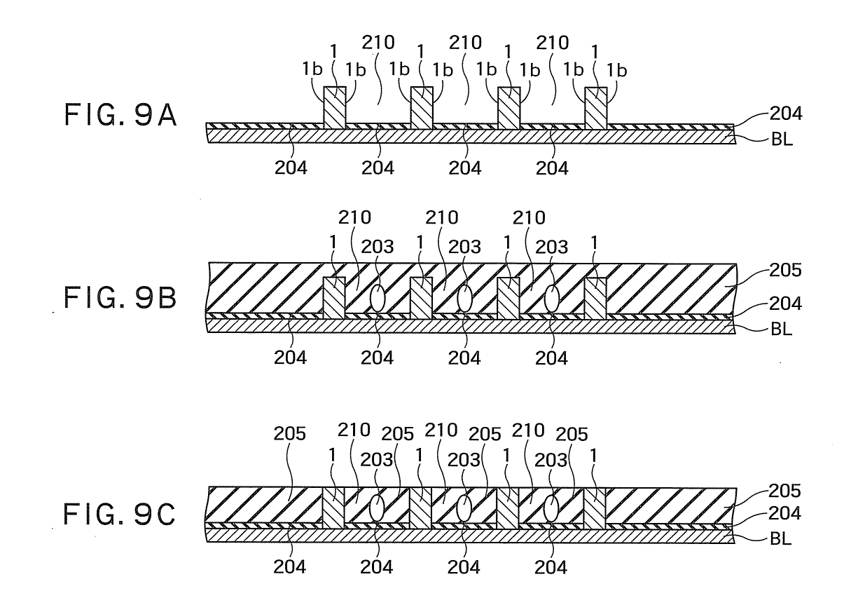

Then, as shown in FIG. 9 A, an upper part of the interlayer insulating film 204 is selectively etched to the height in which a portion of the side surface 1b of the heat source element 1 is exposed.

Then, as shown in FIG. 9 B, an insulating material, such as a silicon oxide film, is deposited on the interlayer insulating film 204 and the heat source elements 1 by, for example, the CVD method or the PVD method such that the void 203 is formed in the space 210 between the upper parts of adjacent heat source elements 1. In this way, the interlayer insulating film 205 including the voids 203 in the spaces 210 between the upper parts of adjacent heat source elements 1 is formed. As described above, the voids 203 prevent heat generated by the heat source element 1 of a certain memory cell M from being transmitted to the phase-change elements 2 of adjacent other memory cells M.

Then, as shown in FIG. 9 C, for example, the upper surface of the interlayer insulating film 205 is planarized by, for example, the CMP method such that the upper surfaces of the heat source elements 2 are exposed.

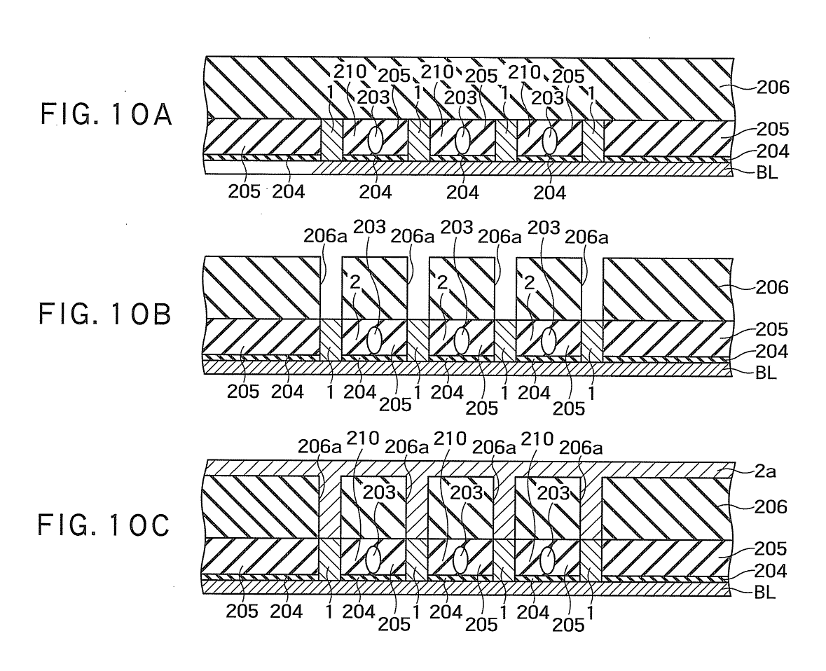

Then, as shown in FIG. 10 A, an insulating material, such as a silicon oxide film, is deposited on the interlayer insulating film 205 and the heat source elements 1 by, for example, the CVD method or the PVD method. In this way, the interlayer insulating film 206 is formed on the interlayer insulating film 205 and the heat source elements 1.

Then, as shown in FIG. 10 B, the interlayer insulating film 206 is selectively etched using, for example, a photoresist (not shown) as a mask. In this way, a plurality of contact holes 206a that pass through the interlayer insulating film 206 and reach the upper surfaces of the heat source elements 1 are formed.

Then, as shown in FIG. 10 C, a phase-change material 2a, such as GeSbTe or AgInSbTe, is deposited on the interlayer insulating film 206 and in the plurality of contact holes 206a by, for example, the CVD method or the PVD method.

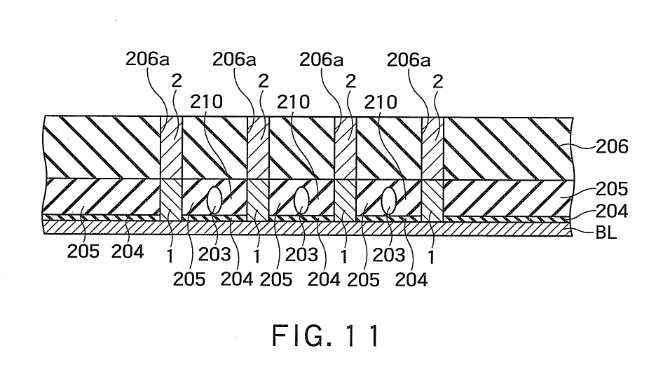

Then, as shown in FIG. 11, the phase-change material 2a on the interlayer insulating film 206 is removed by, for example, a dry etching method. In this way, the phase-change elements 2 are formed on the heat source elements 1 in the plurality of contact holes 206a.

In the second embodiment, as described above, after the heat source elements 1 are formed, the insulating material 205a is deposited between the heat source elements 1, and the voids 203 are formed. After the voids 203 are formed, the phase-change elements 2 are formed. In this way, it is possible to prevent the collapse of the phase-change elements on the heat source elements, as compared to the structure in which the voids are formed after the heat source elements and the phase-change elements are formed.

Then, a plurality of word lines WL that are parallel to each other are formed on the phase-change elements 2 by, for example, a photolithography technique. In addition, for example, the interlayer insulating film 207 is formed on the interlayer insulating film 206 and the word lines WL by, for example, the CVD method or the PVD method. In this way, a structure in the vicinity of the memory cell region of the phase-change memory device 200 shown in FIGS. 6 and 7 is completely formed.

As described above, according to the phase-change memory device of the present embodiment, it is possible to improve the degree of integration and reduce the influence of heat generated by the heat source element of a certain memory cell on the phase-change elements of adjacent other memory cells.

In addition, when the voids are formed in the interlayer insulating film, heat conductivity is lowered, the occurrence of defects in a wet process is reduced, and voltage resistance between the memory cells is increased, as compared to a porous oxide film.

### Third Embodiment

In the first and second embodiments, an example of the structure for preventing heat generated by the heat source element of a certain memory cell from being transmitted to the phase-change elements of adjacent other memory cells has been described.

In a third embodiment, still another example of the structure for preventing heat generated by the heat source element of a certain memory cell from being transmitted to the phase-change elements of adjacent other memory cells will be described.

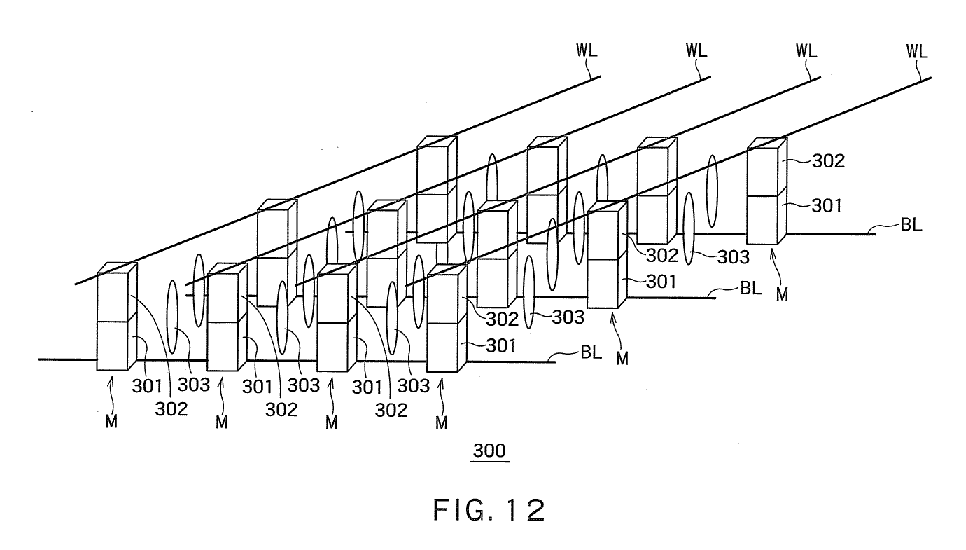

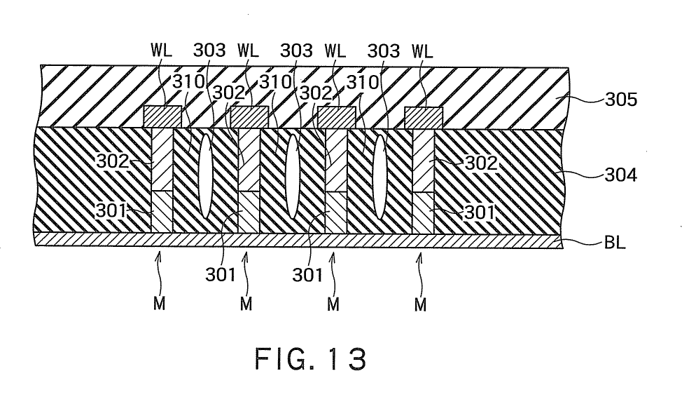

FIG. 12 is a diagram illustrating a structure in the vicinity of a memory cell region in which a plurality of memory cells M are arranged in a phase-change memory device 300 according to the third embodiment. FIG. 13 is a longitudinal cross-sectional view illustrating a region including the memory cells M arranged along the bit lines BL shown in FIG. 12. For convenience, in FIG. 12, the interlayer insulating films shown in FIG. 13 are omitted. In FIG. 12, bit lines BL and word lines WL are briefly shown. In addition, in FIGS. 12 and 13, components denoted by the same reference numerals as those shown in FIGS. 1 and 2 have the similar structure as those according the first embodiment.

As shown in FIGS. 12 and 13, the phase-change memory device 300 includes a plurality of bit lines (wiring lines) BL, a plurality of memory cells M, a plurality of word lines (wiring lines) WL, and interlayer insulating films 304 and 305.

The structure of the phase-change memory device 300 is similar to that of the phase-change memory device 100 according to the first embodiment except for the shape of the memory cell M. That is, the memory cells M of the phase-change memory device 300 have a rectangular parallelepiped shape.

The interlayer insulating film 304 of the phase-change memory device 300 correspond to the interlayer insulating films 4 and 5 of the phase-change memory device 100 according to the first embodiment. In addition, the interlayer insulating film 305 of the phase-change memory device 300 corresponds to the interlayer insulating film 6 of the phase-change memory device 100 according to the first embodiment. A heat source element 301 of the memory cell M of the phase-change memory device 300 corresponds to the heat source element 1 of the memory cell M of the phase-change memory device 100 according to the first embodiment. A phase-change element 302 of the memory cell M of the phase-change memory device 300 corresponds to the phase-change element 2 of the memory cell M of the phase-change memory device 100 according to the first embodiment.

Voids 303 are formed in spaces 310 between the heat source elements 1 and between the phase-change elements 2 of adjacent memory cells M in the interlayer insulating film 304.

The voids 303 prevent heat generated by the heat source element 301 of a certain memory cell M from being transmitted to the phase-change elements 302 of adjacent other memory cells M. In this way, it is possible to reduce the influence of the heat generated by the heat source element 301 of a certain memory cell M on the phase-change elements 302 of adjacent memory cells M (variation in the resistance values of the phase-change elements 302). Therefore, for example, it is possible to prevent data from being erroneously written to the memory cell M, which is not a data write target, or data from being erroneously erased from the memory cell M, which is not a data erase target.

That is, according to the phase-change memory device 300, it is possible to improve the degree of integration and reduce the influence of heat generated by the heat source element of a certain memory cell on the phase-change elements of adjacent other memory cells.

In FIG. 12, the void 303s are provided only between the memory cells that are most closely adjacent to each other (adjacent memory cells connected to the same bit line or the same word line). However, the voids 303 may be provided between adjacent memory cells on a diagonal line according to the relationship between the gap between the memory cells and the coverage of the interlayer insulating film. The above-mentioned structure may be used in order to reduce the influence of the memory cells adjacent to each other on the diagonal line.

Next, an example of a method of manufacturing the phase-change memory device 300 having the above-mentioned structure will be described.

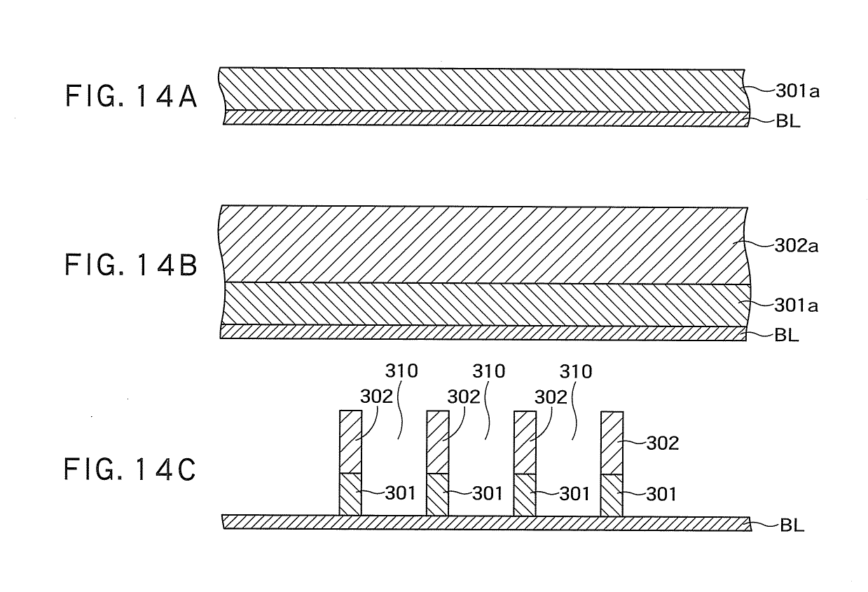

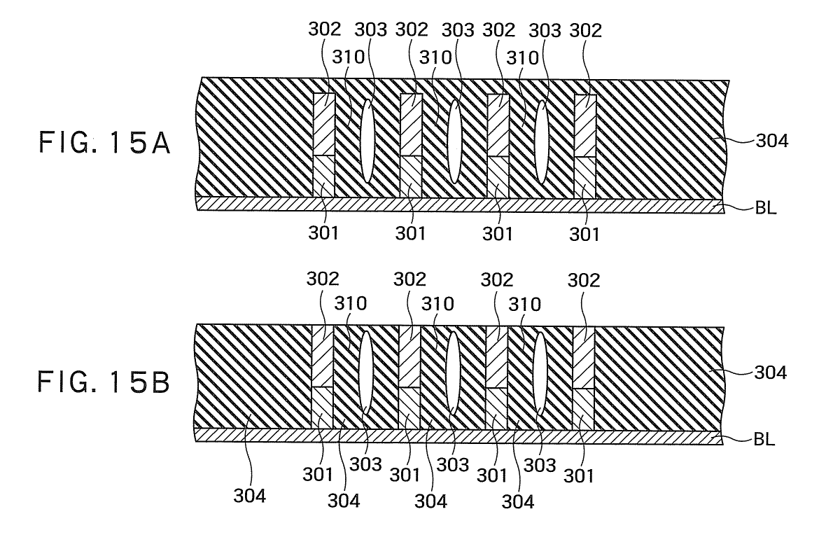

FIGS. 14 and 15 are cross-sectional views illustrating processes of a method of manufacturing a vicinity of a memory cell region of the phase-change memory device 300 shown in FIG. 12. In addition, FIGS. 14 and 15 are longitudinal cross-sectional views illustrating a region including the memory cells M arranged along the bit lines BL shown in FIG. 12, similar to FIG. 13.

First, as shown in FIG. 14 A, a heat source material that is supplied with a current and generates heat is deposited on a region including the plurality of bit lines BL that are parallel to each other by, for example, the CVD method or the PVD method, thereby forming a heat source material layer 301a.

Then, as shown in FIG. 14 B, a phase-change material, such as GeSbTe or AgInSbTe, is deposited on the heat source material layer 301a by, for example, the CVD method or the PVD method, thereby forming a phase-change material layer 302a on the heat source material layer 301a.

Then, as shown in FIG. 14 C, the phase-change material layer 302a and the heat source material layer 301a are selectively etched by, for example, a dry etching method using a photoresist (not shown) as a mask. In this way, the heat source elements 301 are formed and the phase-change elements 302 are formed on the heat source element 301.

Then, as shown in FIG. 15 A, an insulating material, such as a silicon oxide film, is deposited on the region including the bit lines BL by, for example, the CVD method or the PVD method such that the void 303 is formed in a space 310 between two adjacent heat source elements 301 and two adjacent phase-change elements 302. In this way, the interlayer insulating film 304 including the voids 303 formed in the spaces 310 between the two adjacent heat source elements 301 and the two adjacent phase-change elements 302 is formed.

Then, as shown in FIG. 15 B, the upper part of the interlayer insulating film 304 is planarized by, for example, the CMP method such that the upper surfaces of the phase-change elements 302 are exposed.

Then, a plurality of word lines WL that are parallel to each other are formed on the phase-change elements 302 by, for example, a photolithography technique. In addition, for example, the interlayer insulating film 305 is formed on the interlayer insulating film 304 and the word lines WL by, for example, the CVD method or the PVD method. In this way, a structure in the vicinity of the memory cell region of the phase-change memory device 300 shown in FIGS. 12 and 13 is completely formed.

As described above, in the third embodiment, after the heat source elements and the phase-change elements are patterned by, for example, dry etching, each void is formed between the memory cells. That is, the interlayer insulating film between the memory cells is not etched. In this way, it is possible to significantly reduce the number of processes.

As described above, according to the phase-change memory device according to the present embodiment, it is possible to improve the degree of integration and reduce the influence of heat generated by the heat source element of a certain memory cell on the phase-change elements of adjacent other memory cells.

In addition, when the voids are formed in the interlayer insulating film, heat conductivity is lowered, the occurrence of defects in a wet process is reduced, and voltage resistance between the memory cells is increased, as compared to a porous oxide film.

What is claimed is:

1. A phase-change memory device comprising:
a plurality of first wiring lines;
a plurality of memory cells that are provided on the plurality of first wiring lines;
a plurality of second wiring lines that are provided on the plurality of memory cells, respectively; and
an interlayer insulating film that is formed between the plurality of first wiring lines and the plurality of second wiring lines and insulates the plurality of first wiring lines from the plurality of second wiring lines;
wherein each of the memory cells includes a heat source element that is supplied with a current and generates heat and a phase-change element that is changed to an amorphous state or a crystalline state according to a cooling speed after being heated by the heat source element, a resistance value of the phase-change element varying with the change in the state, and
wherein a void is formed between the two adjacent memory cells in the interlayer insulating film.

2. The phase-change memory device according to claim 1,
wherein the void is formed so as to have a segment that divides a shortest distance between the two adjacent memory cells into two equal parts.

3. The phase-change memory device according to claim 1,
wherein the void is formed so as to extend from an upper surface of the heat source element to an upper surface of the phase-change element between the two adjacent memory cells in the interlayer insulating film.

4. The phase-change memory device according to claim 3,
wherein the void is formed so as to have a segment that divides a shortest distance between the two adjacent memory cells into two equal parts.

5. The phase-change memory device according to claim 1,
wherein the void is formed between the two phase-change elements and between upper parts of the two heat source elements of the two adjacent memory cells in the interlayer insulating film.

6. The phase-change memory device according to claim 5,
wherein the void is formed so as to have a segment that divides a shortest distance between the two adjacent memory cells into two equal parts.

7. The phase-change memory device according to claim 1,
wherein the void is formed between the upper parts of the two heat source elements of the two adjacent memory cells in the interlayer insulating film.

8. The phase-change memory device according to claim 7,
wherein the void is formed so as to have a segment that divides a shortest distance between the two adjacent memory cells into two equal parts.

9. The phase-change memory device according to claim 5,
wherein the void is formed so as to extend from a space between the two adjacent phase-change elements to a space between the upper parts of the two adjacent heat source elements.

10. The phase-change memory device according to claim 9,
wherein the void is formed so as to have a segment that divides a shortest distance between the two adjacent memory cells into two equal parts.

11. The phase-change memory device according to claim 1,
wherein the phase-change element includes any of GeSbTe, AgInSbTe, GeSb, GaSb, or GeGaSb.

12. A method of manufacturing a phase-change memory device, the method comprising:
forming a first interlayer insulating film on a region including first wiring lines;
selectively etching the first interlayer insulating film to form a plurality of contact holes that pass through the first interlayer insulating film and reach the first wiring lines;
depositing a heat source material at least in the plurality of contact holes;
etching the heat source material deposited in each of the contact holes to a predetermined height of the contact hole to form a plurality of heat source elements;
forming a phase-change material on the heat source elements in the contact holes to form a plurality of phase-change elements;
selectively etching an upper surface of the first interlayer insulating film until an entire side surface of each of the phase-change elements is exposed and a portion of a side surface of each of the heat source elements is exposed;
forming a second interlayer insulating film on the first interlayer insulating film and the phase-change elements such that a void is formed between the two adjacent phase-change elements;
planarizing an upper surface of the second interlayer insulating film such that the upper surfaces of the phase-change elements are exposed; and
forming second wiring lines on the phase-change elements.

13. The method according to claim 12,
wherein the void is formed so as to have a segment that divides a shortest distance between the two adjacent phase-change elements into two equal parts.

14. The method according to claim 12,
wherein the phase-change element includes any of GeSbTe, AgInSbTe, GeSb, GaSb, or GeGaSb.

15. A method of manufacturing a phase-change memory device, the method comprising:
forming a heat source material layer on a region including a plurality of first wiring lines;
forming a phase-change material layer on the heat source material layer;
selectively etching the phase-change material layer and the heat source material layer to form heat source elements and phase-change elements;
forming an interlayer insulating film on the region including the plurality of first wiring lines such that a void is formed between the two adjacent phase-change elements;
planarizing an upper part of the interlayer insulating film such that the upper surfaces of the phase-change elements are exposed; and
forming second wiring lines on the phase-change elements.

16. The phase-change memory device according to claim 15,
wherein the void is formed so as to have a segment that divides a shortest distance between the two adjacent phase-change elements into two equal parts.

17. The method according to claim 15,
wherein the phase-change element includes any of GeSbTe, AgInSbTe, GeSb, GaSb, or GeGaSb.
